(19) United States
(12) Patent Application Publication
(10) Pub. No.: US 2009/0267147 A1
(43) Pub. Date: Oct. 29, 2009

(54) ESD PROTECTED RF TRANSISTOR

(75) Inventors: Johannes A. M. De Boet, Beuningen (NL); Josephus H. B. Van Der Zanden, Best (NL); Petra C.A. Hammes, Ede (NL)

Correspondence Address: NXP, B.V.;NXP INTELLECTUAL PROPERTY & LICENSING, M/S41-SJ, 1109 MCKAY DRIVE, SAN JOSE, CA, 95131, US

(73) Assignee: NXP B.V., Eindhoven (NL)

(21) Appl. No.: 12/297,104

(22) PCT Filed: Apr. 11, 2007
(86) PCT No.: PCT/IB07/51306

§ 371 Date: Oct. 14, 2008

(30) Foreign Application Priority Data
Apr. 14, 2006 (EP) 06112677.7

(51) Int. Cl. H01L 27/06

(52) U.S. Cl. 257/337; 257/E27.016

(57) ABSTRACT

The electronic device comprising a RF transistor (100) that is designed for a fundamental RF frequency and that is integrated with an electrostatic protection structure (250) with a further transistor (200). The transistors are suitably MOS transistors, with a gate, source and drain electrodes, and wherein the sources are coupled to a grounded substrate region. The drain region of the further transistor is coupled to the gate of the RF transistor (100), giving rise to a parasitic diode (300) between the drain region of the further transistor and the grounded substrate region under application of a certain input voltage. A filter (350) is present for filtering the fundamental RF frequency from the parasitic diode (300).

The invention relates to an electronic device comprising a RF transistor that is integrated with an electrostatic protection structure with a further transistor, each of which transistors comprises (1) a gate dielectric layer on a gate region of a semiconductor substrate, (2) a gate on at least a portion of the gate dielectric layer and (3) a source region and a drain region in the semiconductor substrate adjacent the gate, which source regions are coupled to a grounded substrate region,

wherein the drain region of the electrostatic protection structure is coupled to the gate of the RF transistor, giving rise to a parasitic diode between this drain region and the grounded substrate region for a certain input voltage.

Such an electronic device is known from U.S. Pat. No. 6,873,017. The known device comprises an LDMOS transistor as the RF transistor and uses an NMOS transistor as the further transistor. The gate of the LDMOS transistor forms the input, so that the protection structure is coupled between the input and ground. A junction is formed between the drain region of the further transistor and the substrate. A further p-doped region may be present in the substrate directly below the n-doped drain region. When the input voltage to the LDMOS transistor is large, then the protection structure will come into operation and a current flows in the protection structure from the input (e.g. drain) to the source. At negative input voltages a current flows in the parasitic diode from input to the source.

It is a disadvantage of the known device that it is not very well suitable for RF applications. In RF applications, the RF transistor acts as an RF amplifier. It is required for a proper RF operation of the amplifier that the parasitic diode does not influence this operation negatively. The input capacitance may be increased too much, as mentioned in U.S. Pat. No. 6,821,831.

It is therefore an object of the invention to provide an electronic device of the kind mentioned in the opening paragraph that is suitable for use in RF applications.

This is achieved in that the RF transistor is an RF MOS transistor that is designed for a fundamental RF frequency, and that a filter is present for filtering the fundamental RF frequency from the parasitic diode.

RF amplifiers are usually operated in Class AB. This implies that the DC voltage on the gate of the RF transistor is just above the threshold value. However, the gate is in the present device also the input of the RF transistor. Hence, the input signal comprises both a DC signal and an RF signal, with varying amplitude during an RF cycle. In case of a sudden burst of the RF signal, its amplitude may be larger than the DC signal. This may cause that the resulting voltage on the gate (i.e. V_{gs}) is negative for a portion of the RF cycle. Such negative gate-voltage leads to forward biasing of the parasitic diode in the protection structure, and possibly current flow in the reverse direction, e.g. from source to gate.

As a result of the current flow through the parasitic diode during that portion of the RF cycle, when the voltage is negative, the resulting average voltage (which is the effective DC voltage) increases. It has turned out that under certain conditions this increase of the DC voltage is not corrected immediately. This remaining effect is undesired, as the deviating DC voltage leads to another setting of the RF transistor, and therewith to less efficiency and/or distortion of the RF signal.

According to the invention, the effect can be prevented by including a filter into the protection structure, which filter filters the fundamental frequency of the input RF signal.

The use of such a filter implies that the electrostatic protection structure is ineffective for the fundamental frequency. As discharges may have frequency components up to 5 GHz, this appears problematic. That is however not the case, since the RF transistor is applied in an environment remote from a user interface. The only relevant stage for which protection against electrostatic discharge is needed, is the stages of dicing of a wafer into a plurality of individual products and of assembly. Electrostatic discharges at this stage are less demanding and do not have any such high frequency components.

In view of its behaviour, the protection structure can be considered as a voltage peak detector. This aspect additionally allows the use of the protection structure as such as detector. The detection may be forwarded to a controller, which may correct the input signals if desired.

One of the conditions under which the increase of the DC voltage may remain for some time, and create a memory effect, is the presence of a large impedance on the feed signal. Such a high input impedance is desired for certain broadband applications, for instance in order to provide a large bandwidth for video signals. One example of such broadband application is the communication protocol W-CDMA. A large impedance is herein for instance an impedance of at least 100Ω, more particularly more than 1 kΩ and especially at least 5 kΩ.

The device of the present invention is suitably applied in combination with pre-distortion (e.g. matching of impedances), most particularly with digital predistortion. The problem in combination with such pre-distortion is even more pronounced: the predistortion is not correct anymore. The predistortion may be integrated in the device, but may alternatively be present separately.

Several filter concepts are known to the skilled person, such as notch filters, pi-filters and the like. In one embodiment, the filter is an LC filter. Such a simple filter is effective and may be integrated in the device properly.

In one embodiment, the LC filter is applied between the protection structure and the gate of the RF transistor. Particularly, it is connected such that the input signal can arrive at the gate of the RF transistor without passing the LC filter. The LC filter is then designed to be a resonator, for instance in that the inductor L and the capacitor C are connected in parallel. This embodiment has the advantage that it provides a protection above and below the fundamental RF frequency, but it leads to some loss of performance of the RF transistor.

In another embodiment, the LC filter is connected between the gate of the RF transistor and ground and is provided with an inductor and a capacitor that are connected in series. The drain of the protection structure is then coupled to a node between the inductor and the capacitor of the LC filter. This embodiment has the advantage that it provides some RF prematching of the RF transistor. Such a prematching is particularly needed in a basestation application of the transistor, wherein the requirements to linearity are very high as compared to the use in a mobile phone. A disadvantage is however that the electrostatic protection structure will be effective for frequencies below the fundamental RF frequencies only. It is foreseen that the filter topology may be further improved to have the benefits of both embodiments.

Suitably, a resistor is present between the protection structure and the gate of the RF transistor. This resistor has the function to limit current in case that the protection structure goes into snap back mode. The resistance of the resistor is suitably smaller than 100Ω, more preferably less than 20Ω.

The RF transistor is suitable a MOS transistor of the LDMOS type. More suitably, the RF transistor comprises a double drain extension. Most preferably, there is additionally a shield extending on the gate of the RF transistor and on the first of the drain extensions. A stepped shield structure such as known from wo-A 2005/22645 is preferred.

The further transistor of the protection structure is suitably a grounded cascoded MOS transistor. Most suitably, use is made of a cascoded NMOS transistor.

These and other aspects of the invention will be further discussed with reference to the Figures, in which:

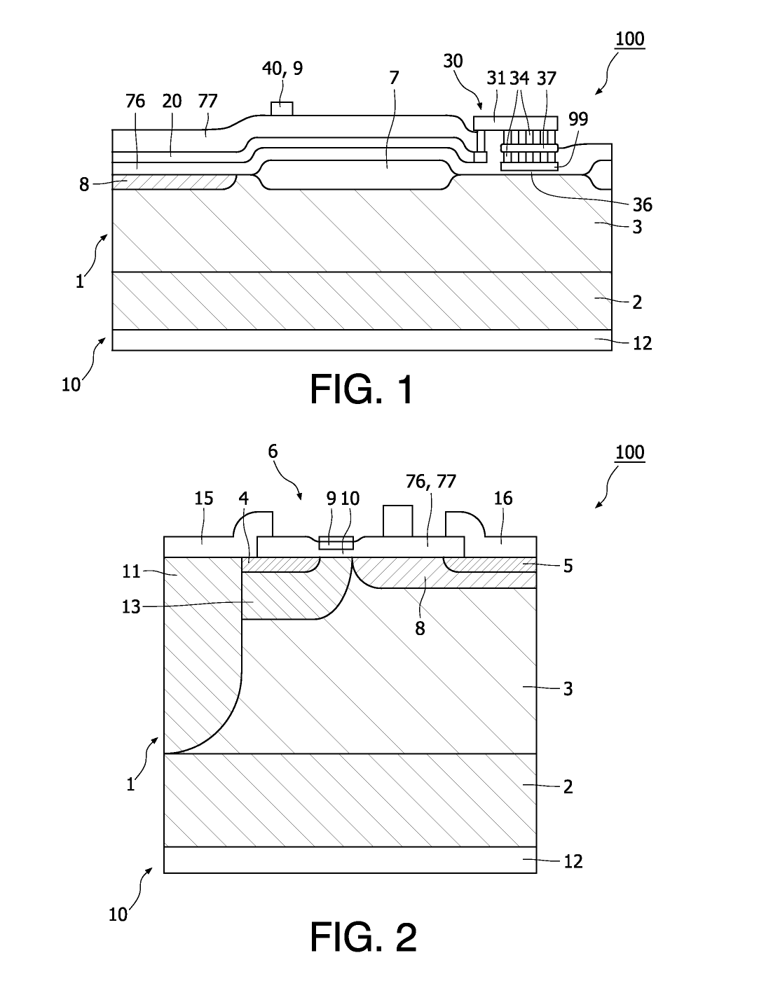

FIGS. 1 and 2 shows a diagrammatical cross-sectional drawing of an RF transistor of the invention;

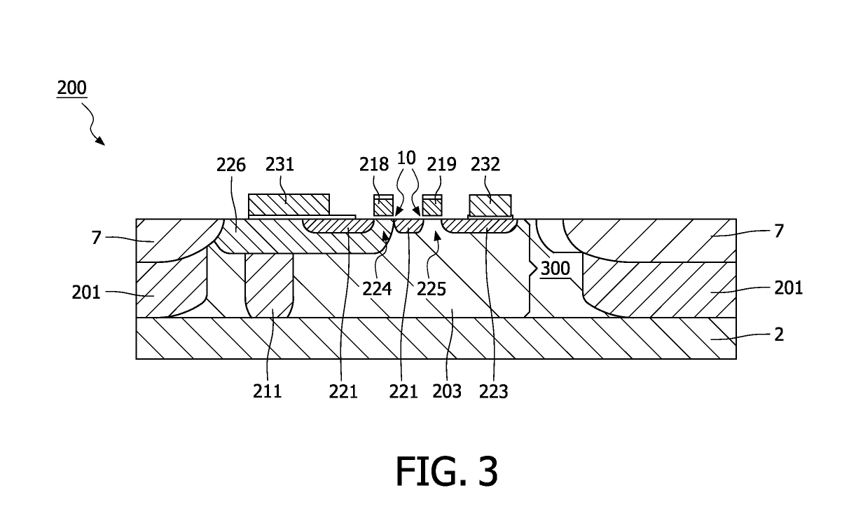

FIG. 3 shows a diagrammatical cross-sectional drawing of the further transistor that is part of the ESD protection structure of the invention;

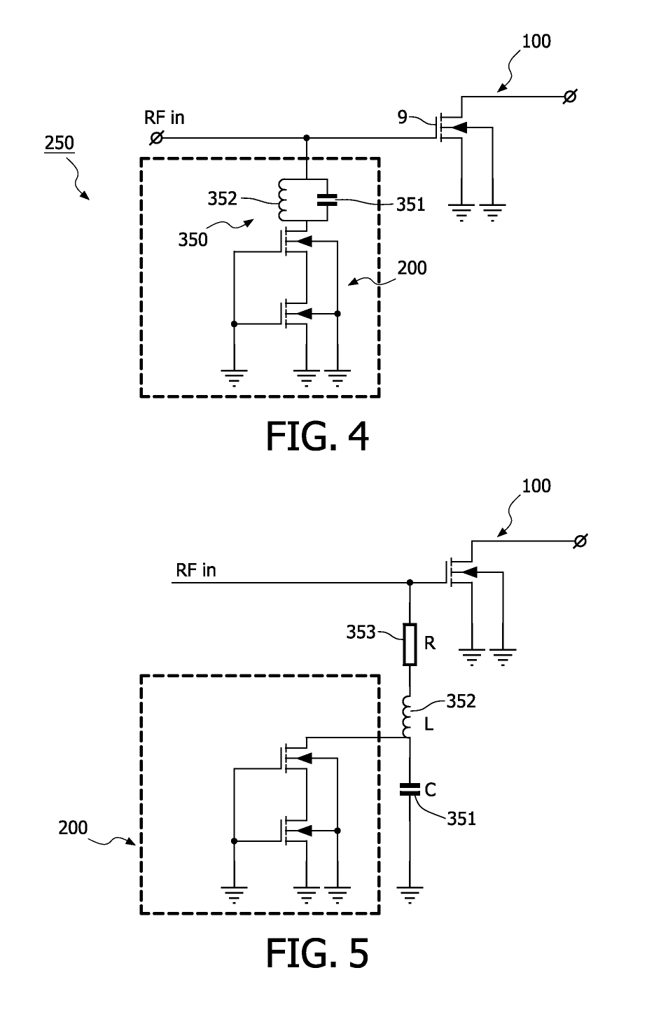

FIG. 4 shows a circuit diagram of a first embodiment of the present invention;

FIG. 5 shows a circuit diagram of a second embodiment of the present invention;

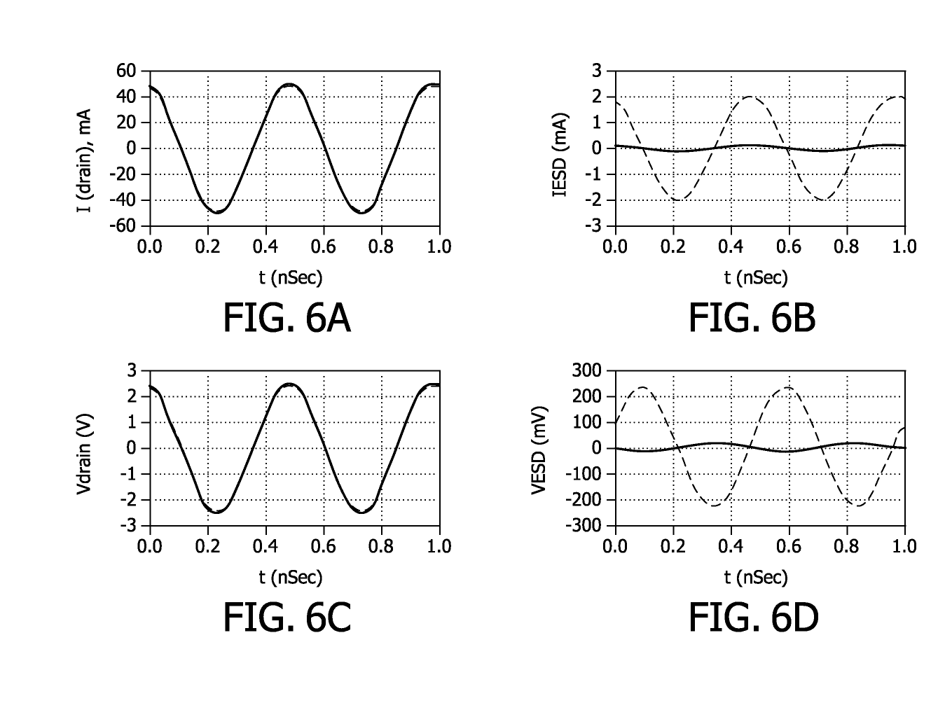

FIG. 6A-D show a plurality of graphs of the current and voltage on the drain of the RF transistor as a function of time.

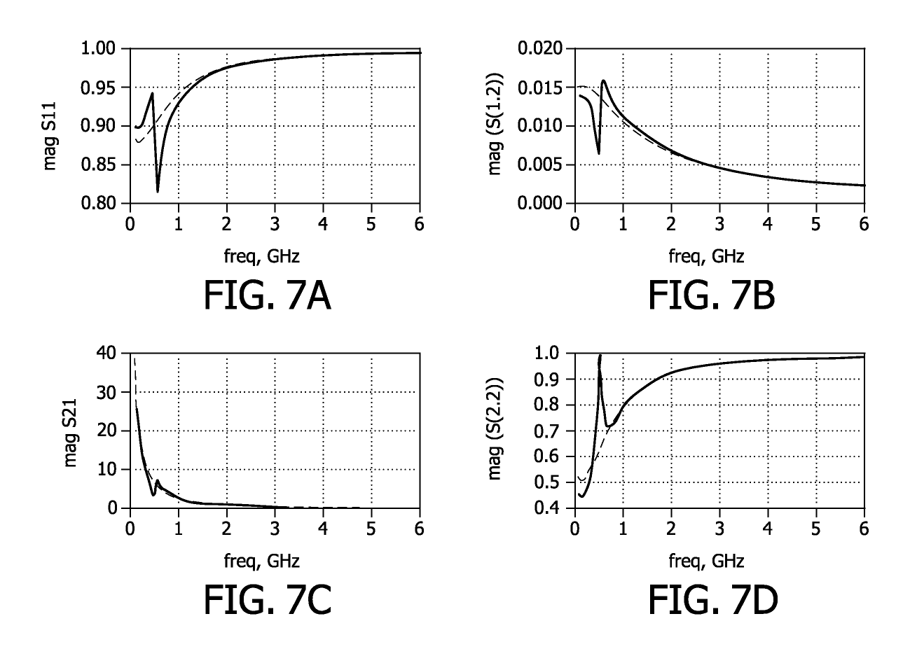

FIG. 7A-D show a plurality of graphs on the frequency dependence of the magnitude of the S-parameters.

The Figures are purely diagrammatical and not drawn to scale. Equal reference numerals in different Figures refer to corresponding parts.

The electronic device of the invention comprises an RF transistor and a further transistor as part of an ESD-protection structure. Both transistors are suitably integrated into a single device and are manufactured in a single process flow. Two embodiments of the circuit relationship between both transistors is shown in FIGS. 4 and 5. FIGS. 1 and 2 show the RF transistor 100. FIG. 3 shows the further transistor 200 that is part of the ESD-protection structure 250.

The device (see FIGS. 1-2) comprises a semiconductor body 1, which is made of silicon in this example, but which may also be made of another suitable semiconductor material, of course. It is provided with an insulating layer 76 of silicon dioxide. The semiconductor body is built up of a low-ohmic, strongly doped p-type substrate 2 and a comparatively weakly doped, high-ohmic region 3 adjoining the surface of the silicon body, in which the transistor is accommodated. In this example, the region 3 is formed by a p-type epitaxial layer having a thickness of approximately 7 μm and a doping concentration of approximately 5.10¹⁵ atoms per cm³. The doping concentration of the substrate 2 which functions as a connection for the source zone is high, for example between 10¹⁹ and 10²⁰ atoms per cm³. An active region 6 is defined in the epitaxial layer, which region is laterally bounded by thick field oxide 7. Source and drain zones of the transistor are provided in the active region in the form of strongly doped n-type surface zones 4 and 5, respectively. The RF transistor 100 comprises a multi-digit structure comprising a number of source/drain digits lying beside one another, which are only shown schematically (FIG. 1) or in part (FIG. 2) in the drawing. The multi-digit structure may be obtained in a simple manner, for example by extending the portion that is shown in FIG. 3 to the left and to the right until the desired channel width is obtained. Preferably, the fingers have a varying threshold voltage in order to improve the linearity behaviour of the RF transistor.

To increase the breakdown voltage, the drain zone 5 is provided with a high-ohmic n-type drain extension 8 between the drain zone 5 and the channel of the transistor. The length of the extension is 3.5 μm in this example. The transistor channel is formed by the p-type region 13 between the extension 8 and the source zone 4. A gate electrode 9 is provided above the channel, which gate electrode is separated from the channel by a gate oxide 10 having a thickness of, for example, 70 nm. The gate electrode 9 is formed by strips of strongly doped, approximately 0.3 μm thick polycrystalline silicon (poly) overlaid with approximately 0.2 μm titanium silicide, which, seen at the surface, extends transversely over the active region 6 between the source zones 4 and the drain extensions 8. The source zone (or zones) 4 is (are) short-circuited with the p-type region via a deep, strongly doped p-type zone 11 which extends from the surface down to the strongly doped substrate and which connects the source zone 4 to the source electrode 12 at the lower side of the substrate via the substrate 2. The RF transistor 100 is embodied as an LDMOST, so that it can be operated at a sufficiently high voltage, for which purpose an additional p-type doping is provided in the channel in the form of the diffused p-type zone 13, so that the doping concentration is locally increased as compared with the weak epi doping.

The surface is coated with a thick glass layer, in which contact windows are provided above the source and drain zones, through which windows the source and drain zones are connected to metal source and drain contacts 15 and 16, respectively. As is apparent from the plan view of FIG. 2, the contacts 15 and 16 are formed by metal strips extending parallel to each other over the glass layer. The source contact 15 is not only connected to the source zone(s), but also to the deep p-type zone 11, and thus interconnects the source zone and the connection 12 at the bottom side of the substrate. The source zone may be connected to external connections via this connection.

The gate electrode 9 of the RF transistor 100 is also provided with a metal contact, which extends in the form of a strip over the oxide layer between the metal strips 15 and 16, and which is locally connected to the gate 9 via contact windows in the oxide layer. The resistance of the gate electrode is also reduced by the presence of titanium silicide thereon. The silicide may be provided in the form of stepped shield. A very low gate resistance can be obtained through the use of a metal having a low resistivity, for example gold or aluminum.

Further metal tracks 20 are provided between the polysilicide tracks of the gate electrode 9 and the A1 tracks 16 of the drain contact. Said tracks 20 are connected to an electrode 31 of a capacitor 30. The (partially interconnected) shielding tracks 20 are connected to the capacitor 30 at evenly spaced positions, said tracks being formed in the lower layer of the two metal layers 20,18 that are separated from each other by means of an insulating silicon dioxide layer 77. The use of a two-metal layer process makes it possible for the metal tracks 20 to cross the gate electrode 9. This makes it possible to connect metal tracks 20 having a minimum resistivity. In this example, another electrode of the capacitor 30 is formed by the portion of the semiconductor body 1 that is present under a thin oxide layer 36, in this case a portion of the epitaxial layer 3 and the substrate 2, which electrode is connected to the source connection 12, therefore. The upper electrode 31 is connected, via metal plugs 34 and an additional metal layer 37 incorporated therein, to a polycrystalline silicon region 99 present on the oxide layer 36 and to the further metal strip 20. In this example, the capacity is 100 pF. The capacitor 30 has been found to have a beneficial effect on the performance of the RF transistor. By application of a voltage to the further metal strip 20, the RF transistor may be considered to comprise a first and a second transistor, the first being an enhancement type transistor, which is associated with the gate electrode, and the second being a depletion type transistor, whose further metal strip 20 forms the gate electrode, as it were.

FIG. 3 shows an embodiment of the transistor 200 in the ESD protection structure. The transistor 200 is a cascaded NMOS transistor that is provided with a first gate 218 and a second gate 219, surface zones 221, 222, 223 and channels 224, 225. The surface zones 221, 222, 223 and the regions 224, 225 acting as channels in the transistor are defined in a further comparatively lowly doped, high-ohmic region 203, which is defined on the highly doped region 2, also known as epi, which extends to the RF transistor 100. The first channel region 224 is defined within a lightly doped region 226, also known as a p-well. The second channel region 225 is however present within the epi 203. Due to this difference, and the resulting implications for the dopant concentration in the channels 224, 225, the threshold voltage is higher for the first channel 224 than for the second channel 225. This difference is implemented in order to achieve a cascode effect. The second surface zone 222 forms a connection between said channels 224 and 225, and is not provided with a separate electrode or contact. The gates 218, 219 are coupled to ground.

The surface zone 221 acts herein as a source, which is coupled to ground. The surface zone 223 acts as a drain, and is coupled to the input of the RF transistor 200 via further components. A deep diffusion 211, in this example p-type doped and formed in the same manner as the region 11, suitably formed simultaneously therewith, extends between the surface zone 221 and the highly doped region 2. Although FIG. 3 tends to suggest that the deep diffusion 211 extends to the p-well 224 only, this appears a matter of diagrammatical representation.

An insulating region 201 is defined around the high-ohmic region 203, so as to separate this transistor 200 from the RF transistor 100 and/or any further transistors. This insulating region 201 is also known as a channel stopper. A gate oxide 210 is present between the gate electrode 218, 219 and the corresponding channels 224, 225. The source and drain 221, 223 are further provided with metal contacts 231, 233, suitably defined in a silicide layer. The gate electrodes 218, 219 are suitably defined in polysilicon, as known to the skilled person. Further connections to the contacts 231, 233 and gate electrodes 218, 219 are not shown, but evidently available.

It is observed that the double gated NMOS transistor 200 is only an example, although a preferred one. A transistor without a second gate 219 and second channel 224 could be chosen alternatively, but this would lower the trigger voltage of the ESD protection structure. Lowering of the trigger voltage has the risk that the ESD protection opens already during normal operation, due to the provision of RF signals. The risk is evidently dependent on the amount of lowering, as well as the normal voltage; if the present RF transistor is a final stage of an amplifier, with preceding amplification stages, the risk is evidently larger than if the RF transistor is the first or the signal stage.

According to the invention, the further transistor 200 is coupled to the gate 9 of the RF transistor 100, which functions as an input. For instance it may be connected to the bond pad for the input signal, and also to a gate line. The further transistor 200 is suitably smaller than the RF transistor 100, particularly if the RF transistor is an RF power transistor. Preferably, its overall channel width is less than 2% than that of the RF transistor, and more preferably even less than 0.5% or even 0.2% or less.

The coupling of the drain region 223 of the further transistor 200 is coupled to the gate 9 of the RF transistor 100 gives rise to a parasitic diode 300 between the drain region 223 of the further transistor 200 and the grounded substrate region 2. The parasitic diode 300 comes into existence due to the fact that the drain region 223 is doped with a dopant of opposite type to that of the underlying lowly doped region 203. Under normal operations, the parasitic diode 300 does not give problems, but it may give problems with a large input voltage.

In the present transistor design, problems were observed with input voltages larger than 2 V, and more dramatically with input voltages larger than 5 V, but this is dependent on the transistor design. Generally, it may turn up when the peak voltage of the RF signal is larger than the DC voltage on the gate. Here, it must be understood that RF signals have an amplitude that changes with time, according to a for instance sinusoidal behaviour. The time of one RF cycle is herein set by the frequency band. This implies that the peak voltage and/or the peak current is achieved only during a portion of the RF cycle, and that the peak can be very large even if the average voltage is limited.

In case of such larger peak voltage of the RF signal than the DC voltage, the voltage difference between gate 9 and source of the RF transistor 100 is negative for a portion of the RF cycle. The current then has a tendency to flow in the opposite direction. Under these conditions, the parasitic diode 300 is biased in forward and opened, and the current will flow from the gate 9 of the RF transistor 100 through the diode 300 to the ground 2.

The mere flow of current through the parasitic diode 300 does not give any problems in itself. The problem relates particularly to a memory effect that may turn up. Such a memory effect is observed with larger impedances in the DC line, particularly an impedance of more than 20 ohm, particularly more than 100 ohm, and more specifically with an input impedance of more than 1 kohm. Such a large input impedance creates an increase of the DC voltage on the gate 9 of the RF transistor 100. In other words, the negative voltage difference between gate and source of the RF transistor 100 does not turn up, except for larger peak voltages. Here is a minor risk that the breakdown voltage of the RF transistor 100 is exceeded. Additionally, and more important, such an increase of the DC voltage may undermine the desired control of the RF transistor and lead to decrease of RF performance of the RF transistor. This is particularly due to a memory effect, as will be explained below

These problems are solved in the invention, in that a filter 350, as shown in FIGS. 4 and 5, is present for filtering the fundamental RF frequency from the parasitic diode. The insight behind this solution is that the parasitic diode tends to lead to said memory effect. One may understand this as a consequence of resonance, while certain delays and/or differences in characteristic frequencies of the diode and the RF transistor may play a role. The delay is particularly large in case of larger impedance needed for large bandwidth. The memory effect implies that the voltage on the gate is not correct during a period that the flow of current through the parasitic diode is remembered. Moreover, due to the dependence of the DC voltage increase on the history of the input signal, the distortion is not predictable, and predistortion is not accurately possible.

Now by ensuring that any signal having the fundamental frequency of the application does not enter the diode, the unexpected contribution of the parasitic diode to the DC voltage is reduced, up to negligible or zero contribution.

Different filter operations may be used in order to arrive at the required effect. According to one embodiment, the signal at the fundamental frequency and suitably a certain frequency band around this, is distributed away to ground. According to another embodiment, a transformation takes place to a frequency that is outside the frequency band of operation. This transformed frequency can be a lower frequency or a higher frequency. Suitably, it is a lower frequency, for instance in the band between 100 MHz and 1 GHz, and more particularly between 400 and 700 MHz.

Preferably, use is made of an LC-filter to catch the characteristic frequency. It is observed herein that the inductor of this LC filter does not interfere with any bond wire present on a bond pad in the immediate neighbourhoud, f.i. on the bond pad for the input signal. Lack of interference is achieved in that the field of the inductor extends in the same direction as the bond wire. Most suitably, the inductor and capacitor of the filter are arranged in areas on the electronic device that are conventionally kept entry in view of the optimization of the design of the RF transistor. Herewith, the improvement in reliability is achieved without any size increase.

FIGS. 4 and 5 each show an embodiment of the circuit according to the invention. In both embodiments, the filter 350 is an LC filter, having a capacitor 351 and an inductor 352. FIG. 4 shows a configuration in which the LC filter 350, with the capacitor 351 and inductor 352 parallel to each other, is connected in series with the further transistor 200. It is present between the RF transistor 100 and the further transistor 200. The LC filter 350 forms a resonator that is designed to resonate at the fundamental frequency of the application. This solution can be used as “plug-in”, with the disadvantage that some RF-losses will occur in the resonator.

FIG. 5 shows another configuration, in which the capacitor 351 and the inductor 352 are coupled in series. The further transistor 200 is herein connected to the node between the capacitor 351 and the inductor 352. The inductor 352 is herein further coupled to the gate 9 of the RF transistor 100, while the capacitor 351 is further coupled to ground. This embodiment has as additional advantage, that it provides some RF pre-matching. It therewith reduces the losses that the filter 350 introduces. A disadvantage is however that the ESD-protection device 250 is only effective for frequency components below the application frequency. The ESD protection level is further decreased compared to the embodiment shown in FIG. 4. A resistor 330 can be added to improve the stability of the circuit.

FIGS. 6 and 7 show graphs that result from simulations on the second embodiment as shown in FIG. 5. For the aim of the simulation, merely the parasitic diode 300 was included in the simulation model. The capacitance of the parasitic diode 300 was assumed to be 0.7 pF. The capacitance of the capacitor 351 was assumed to be 10 pF. The inductance of the inductor 352 was assumed to be 10 nH, and the resistance of the resistor 330 was 3.5 ohm.

FIG. 6 comprises four graphs. In each of the graphs, the dotted line relates to an unfiltered situation, whereas the normal line relates to the device according to the invention. FIG. 6a and FIG. 6b disclose the relationship of current versus elapsed time. FIG. 6c and FIG. 6 disclose the relationship of voltage versus elapsed time. FIG. 6a and FIG. 6c relate to the current and voltage of the drain of the RF transistor 100. FIG. 6b and FIG. 6d relate to the current and voltage on the further transistor 200. The graphs indicate the time in nanoseconds, the current in milliampères. The voltage is indicated in Volts in FIG. 6c and in millivolts in FIG. 6d. It can be derived from the figures that the operation frequency is 2 GHz.

FIGS. 6a and 6c show that the effect of the addition of the filter on the drain current and the drain voltage is negligible. That implies that the filter does not affect the RF performance negatively, at least not to a significant level.

FIGS. 6b and 6d show that the effect of the filter on the further transistor 200 is substantial. The amplitudes of the current and voltage on the further transistor 200 have decreased approximately 20-fold. It is thus clear that the filter shield the further transistor 200 from the RF signal.

FIG. 7 shows graphs in which the magnitude of S-parameters is shown as a function of the frequency of the signal. As in FIG. 6, the dotted line relates to an unfiltered configuration of an RF transistor and a further transistor, while the normal line relates to the device according to the invention. In the S-parameters shown here, the index 1 relates to the input, and the index 2 relates to the output. FIG. 7a shows the S11, which is the return loss. FIG. 7b shows the S12, which relates to losses due to current flowing in opposite direction. FIG. 7c shows the S21, which is the gain. FIG. 7d shows the reflection loss.

As is clear from observation of FIG. 7, the graphs for the device according to the invention show a non-ideal effect at a frequency of approximately 600 MHz, and is otherwise equal. However, this non-ideal effect occurs at a frequency outside a relevant frequency band, and is thus irrelevant for the operation of the device. The non-ideal effect is assumed due to resonance of the filter. Its origin is in parasitic effects of the components in the filter, and in particular, a parasitic capacitance of the inductor.

In short, due to the insertion of a filter for filtering the fundamental frequency between an RF transistor and a further transistor for ESD protection, memory effects are prevented, while the RF performance is not affected negatively in the frequency band relevant for the application. Therewith, reliability of the solution is improved. The solution is suitable for all frequency, but particularly relevant for the W-CDMA protocol.

REFERENCE NUMERALS:

| | |
|---|---|
| 1 | semiconductor body |
| 2 | strongly doped p-type substrates |
| 3 | comparatively weakly doped, high ohmic region |
| 4 | n-type surface zone (source zone) |
| 5 | n-type surface zone (drain zone) |
| 6 | active region |
| 7 | field oxide |
| 8 | extension of drain zone 5 |
| 9 | gate electrode |
| 10 | gate oxide |
| 11 | deep strongly doped p-type zone forming connection between |
| | source zone 4 and source electrode 12 |
| 12 | source electrode (back side contact) |
| 13 | p-type region forming channel |
| 15 | source contact (front side contact) |
| 16 | drain contact (front side contact) |
| 20 | further metal shielding tracks |
| 30 | capacitor |
| 31 | electrode of capacitor 30 |
| 34 | metal plug |
| 36 | oxide layer |
| 37 | additional metal layer |
| 76 | insulating layer |
| 77 | silicon dioxide layer of the capacitor |
| 99 | polycrystalline silicon region |
| 100 | RF transistor |
| 200 | further transistor |
| 201 | isolation around zone 203, also called channel stopper |
| 203 | region that is comparatively lowly doped with respect to |
| | the region 2 |
| 210 | gate oxide |
| 211 | deep diffusion extending between source 221 and region 2 |
| 218 | first gate electrode |
| 219 | second gate electrode |
| 221 | first surface zone of transistor 200, acting as a source |
| 222 | second surface zone of transistor 200 |
| 223 | third surface zone of transistor 200, acting as a drain |
| 224 | channel region extending between first and second surface |
| | zone 221, 222 |
| 225 | channel region extending between second and third surface |
| | zone 222, 223 |
| 231 | contact to the source 221 |
| 232 | contact to the drain 222 |
| 250 | ESD protection structure |
| 300 | parasitic diode |
| 350 | filter |
| 351 | capacitor of the filter |
| 352 | inductor of the filter |

1. An electronic device comprising a RF transistor intergrated with an electrostatic protection structure with a further transistor, each of which transistors comprises (1) a gate dielectric layer on a gate region of a semiconductor substrate, (2) a gate on at least a portion of the gate dielectric layer and (3) a source region and a drain region in the semiconductor substrate adjacent the gate, which source regions are coupled to a grounded substrate region,
wherein the drain region of the further transistor is coupled to the gate of the RF transistor, giving rise to a parasitic diode between the drain region of the further transistor and the grounded substrate region under application of a certain input voltage, and
wherein a filter is present for filtering a fundamental RF frequency from the parasitic diode.

2. An electronic device as claimed in claim 1, wherein the filter is an LC filter.

3. An electronic device as claimed in claim 1, wherein the filter is connected between the drain of the further transistor and the gate of the RF transistor.

4. An electronic device as claimed in claim 2, wherein the filter is coupled between the gate of the RF transistor and the ground, while the ESD protection structure is connected to a node between an inductor and a capacitor of the LC filter.

5. An electronic device as claimed in claim 1, wherein a resistor is present between the ESD protection structure and the gate of the RF transistor.

6. An electronic device as claimed in claim 5, wherein the resistor is at least 1 kOhm.

7. An electronic device as claimed in claim 1, wherein the electrostatic protection structure comprises a grounded cascoded transistor.

8. An electronic device as claimed in claim 1, wherein the further transistor is a NMOS transistor.

9. An electronic device as claimed in claim 1, wherein the RF transistor is an LDMOS transistor.

10. An electronic device as claimed in claim 2, wherein the device is provided in an MMIC configuration.

11-12. (canceled)
